(19) United States
(12) Patent Application Publication
(10) Pub. No.: US 2024/0215241 A1
(43) Pub. Date: Jun. 27, 2024

(54) THREE-DIMENSIONAL MEMORY DEVICES AND FABRICATING METHODS THEREOF

(71) Applicant: Yangtze Memory Technologies Co., Ltd., Wuhan (CN)

(72) Inventors: Liang XIAO, Wuhan (CN); Qian LI, Wuhan (CN); Shu WU, Wuhan (CN); Ziqun HUA, Wuhan (CN)

(73) Assignee: Yangtze Memory Technologies Co., Ltd., Wuhan (CN)

(21) Appl. No.: 18/361,189

(22) Filed: Jul. 28, 2023

Related U.S. Application Data
(60) Provisional application No. 63/434,893, filed on Dec. 22, 2022.

(30) Foreign Application Priority Data
Jul. 4, 2023 (CN) 202310815900.0

(51) Int. Cl. H10B 43/27; H01L 25/065; H01L 25/18; H10B 41/27; H10B 80/00

(52) U.S. Cl. CPC H10B 43/27; H01L 25/0657; H01L 25/18; H10B 41/27; H10B 80/00

(57) ABSTRACT

The present disclosure provides a memory device. The memory device can include an alternating layer stack comprising dielectric layers and conductive layers stacked in a first direction. The memory device can also include a channel structure extending through the alternating layer stack in a first direction in a first region. A first material layer may be disposed on the channel structure. The memory device can also include a first dummy channel structure extending through the alternating layer stack in the first direction in a second region abutting the first region. A second material layer may be disposed on the first dummy channel structure. The first material layer and the second material layer may be different materials. The first material layer may be spaced apart from the first dummy channel structure in a second direction. The first direction may be perpendicular to the second direction.

### REFERENCE TO RELATED APPLICATION

This application claims priority to Chinese Patent Application No. 202310815900.0 filed on Jul. 4, 2023, and U.S. Provisional Patent Application No. 63/434,893, titled “MEMORY SYSTEM, MEMORY AND METHOD FOR FORMING THE SAME,” filed on Dec. 22, 2022, the disclosures of both of which are incorporated by reference herein in their entireties.

### TECHNICAL FIELD

The present disclosure generally relates to the field of semiconductor technology, and more particularly, to a three-dimensional (3D) memory device.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices.

Planar memory cells are scaled to smaller sizes by improving process technology, circuit designs, programming algorithms, and fabrication processes. However, as feature sizes of the memory cells approach a lower limit, planar processes and fabrication techniques have become challenging and costly. As such, memory density for planar memory cells approaches an upper limit. A three-dimensional (3D) memory architecture can address the density limitation in planar memory cells.

### BRIEF SUMMARY

Embodiments of a three-dimensional (3D) memory device and methods for forming the same are described in the present disclosure.

Some aspects of this disclosure relate to a memory device. The memory device can include an alternating layer stack comprising dielectric layers and conductive layers stacked in a first direction. The memory device can also include a channel structure extending through the alternating layer stack in a first direction in a first region. A first material layer may be disposed on the channel structure. The memory device can also include a first dummy channel structure extending through the alternating layer stack in the first direction in a second region abutting the first region. A second material layer may be disposed on the first dummy channel structure. The first material layer and the second material layer may be different materials. The first material layer may be spaced apart from the first dummy channel structure in a second direction. The first direction may be perpendicular to the second direction.

According to some aspects, the second material layer can be disposed on the first material layer.

According to some aspects, the second material layer can include a dielectric material.

According to some aspects, the first material layer can include a conductive material.

According to some aspects, the memory device can further include a second dummy channel structure in the second region. A third material layer can be disposed on the second dummy channel structure.

According to some aspects, the third material layer can include a conductive material.

According to some aspects, the second dummy channel structure can be filled with an insulating material.

According to some aspects, a depth of the first dummy channel structure can be greater than a depth of the second dummy channel structure in the first direction.

According to some aspects, the first dummy channel structure may not be electrically connected with the first material layer.

According to some aspects, a depth of the first dummy channel structure can be greater than a depth of the channel structure in the first direction.

According to some aspects, the first material layer can be disposed on a channel layer of the channel structure. The first material layer can be electrically connected with the channel layer.

According to some aspects, the memory device can further include a staircase structure in a third region abutting the second region. The staircase structure can include the alternating layer stack.

According to some aspects, the memory device can further include a contact structure in the third region. The contact structure can be electrically connected with one of the conductive layers of the alternating layer stack.

According to some aspects, the memory device can further include a barrier structure in the third region. The barrier structure can include a conductive material.

According to some aspects, one of the dielectric layers can be disposed over a first portion of one of the conductive layers. A landing pad can be disposed over a second portion of the one of the conductive layers.

Some aspects of this disclosure relate to a memory system. The memory system can include a controller and a memory device coupled to the controller. The memory device can include an alternating layer stack comprising dielectric layers and conductive layers stacked in a first direction. The memory device can also include a channel structure extending through the alternating layer stack in a first direction in a first region. A first material layer can be disposed on the channel structure. The memory device can also include a first dummy channel structure extending through the alternating layer stack in the first direction in a second region abutting the first region. A second material layer can be disposed on the first dummy channel structure. The first material layer and the second material layer can be different materials. The first material layer can be spaced apart from the first dummy channel structure in a second direction. The first direction can be perpendicular to the second direction.

Some aspects of this disclosure relate to a method for forming a memory device. The method can include disposing an alternating layer stack on a substrate. The alternating layer stack can include dielectric layers and conductive layers stacked in a first direction. The method can also include forming a channel structure extending through the alternating layer stack in the first direction in a first region. The method can also include disposing a first material layer on the channel structure. The method can also include forming a first dummy channel structure extending through the alternating layer stack in the first direction in a second region abutting the first region. The method can also include disposing a second material layer on the first dummy channel structure. A second material layer can be disposed on the first dummy channel structure. The first material layer and the second material layer can be different materials. The first material layer can be spaced apart from the first dummy channel structure in a second direction. The first direction can be perpendicular to the second direction.

According to some aspects, the method can further include disposing the second material layer on the first material layer.

According to some aspects, the forming the first dummy channel structure can include disposing the first material layer on the first dummy channel structure; and removing the first material layer.

According to some aspects, the disposing the first material layer on the channel structure can include disposing a protective layer on the first material layer; and removing the protective layer.

According to some aspects, the method can further include forming a second dummy channel structure in the second region; and disposing a third material layer on the second dummy channel structure.

According to some aspects, the method can further include disposing an insulating material in the second dummy channel structure.

According to some aspects, a depth of the first dummy channel structure can be formed greater than a depth of the second dummy channel structure in the first direction.

According to some aspects, the first dummy channel structure may not be electrically connected with the first material layer.

According to some aspects, a depth of the first dummy channel structure can be formed greater than a depth of the channel structure in the first direction.

According to some aspects, the method can further include forming a staircase structure in a third region abutting the second region. The staircase structure can include the alternating layer stack.

According to some aspects, the method can further include forming a contact structure in the third region. The contact structure can be electrically connected with one of the conductive layers of the alternating layer stack.

According to some aspects, the method can further include forming a barrier structure in the third region. The barrier structure can include a conductive material.

According to some aspects, the method can further include disposing one of the dielectric layers over a first portion of one of the conductive layers; and disposing a landing pad over a second portion of the one of the conductive layers.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate embodiments of the present disclosure and, together with the description, further serve to explain the principles of the present disclosure and to enable a person skilled in the pertinent art to make and use the present disclosure.

FIG. 1A illustrates a block diagram of an electronic system having a memory device, according to some aspects of the present disclosure.

FIG. 1B illustrates a diagram of a memory card having a memory device, according to some aspects of the present disclosure.

FIG. 1C illustrates a diagram of a solid-state drive (SSD) having a memory device, according to some aspects of the present disclosure.

FIG. 1D illustrates a schematic diagram of a memory device including peripheral circuits, according to some aspects of the present disclosure.

FIGS. 1E and 1F illustrates cross-sectional illustrations of 3D memory device according to some aspects of the present disclosure.

FIG. 2 illustrates a flow diagram of forming an exemplary three-dimensional (3D) memory device, according to some embodiments of the present disclosure.

FIGS. 3-7 illustrate schematic cross-sectional views of various fabrication stages of a 3D memory device, according to some embodiments of the present disclosure.

The features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

Embodiments of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other embodiments whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and can, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of lateral planes between, or at, a top surface and a bottom surface of the continuous structure. A layer can extend laterally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

In the present disclosure, for ease of description, “tier” is used to refer to elements of substantially the same height along the vertical direction. For example, a word line and the underlying gate dielectric layer can be referred to as “a tier,” a word line and the underlying insulating layer can together be referred to as “a tier,” word lines of substantially the same height can be referred to as “a tier of word lines” or similar, and so on.

As used herein, the term “nominal/nominally” refers to a desired, or target, value of a characteristic or parameter for a component or a process step, set during the design phase of a product or a process, together with a range of values above and/or below the desired value. The range of values can be due to slight variations in manufacturing processes or tolerances. As used herein, the terms “about” and “substantially” indicate the value of a given quantity that can vary based on a particular technology node associated with the subject semiconductor device. Based on the particular technology node, the term “about” and “substantially” can indicate a value of a given quantity that varies within, for example, 10-30% of the value (e.g., +10%, +20%, or +30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

As the development of 3D memory (e.g., 3D NAND flash memory) progress towards high density and high capacity memory cells, a dummy channel structure (DCH) can be formed in a memory device. The dummy channel structure may play a supporting role in the process of replacing the gate layer. According to some aspects, the dummy channel structure and the channel structure in the memory device can adopt the same fabrication process or step, so that the dummy channel structure and the channel structure can include the same layer structure, such as a conductive layer (e.g., polysilicon).

According to some aspects, in the process of forming a memory device, the depth of a dummy channel structure and a channel structure formed may be inconsistent, such as the depth or height of the dummy channel structure can be greater than the depth or height of the channel structure. In the subsequent processes, an electrical connection between the conductive layer in the dummy channel structure and the source layer (e.g., polysilicon) connected with the dummy channel structure and the channel structure the may cause leakage problems, which may affect the performance of the memory device.

Various embodiments in accordance with the present disclosure provide structures and fabricating methods for forming a 3D memory device.

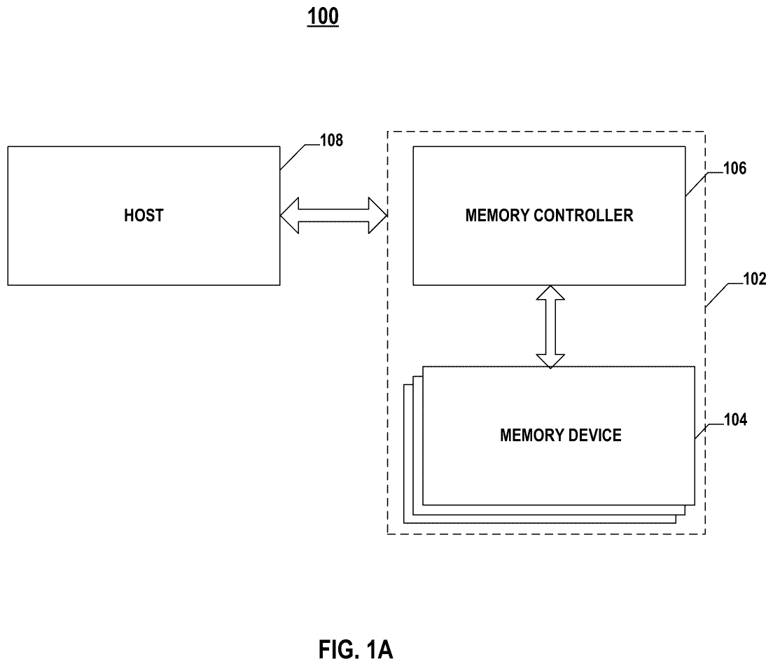

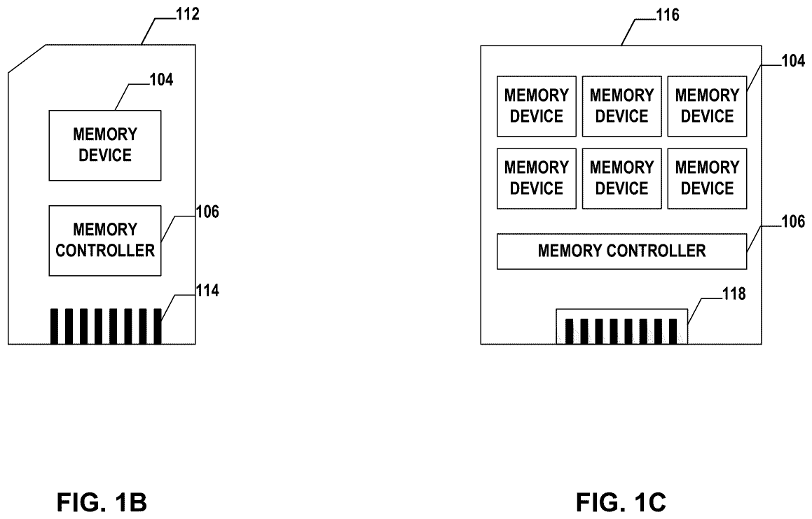

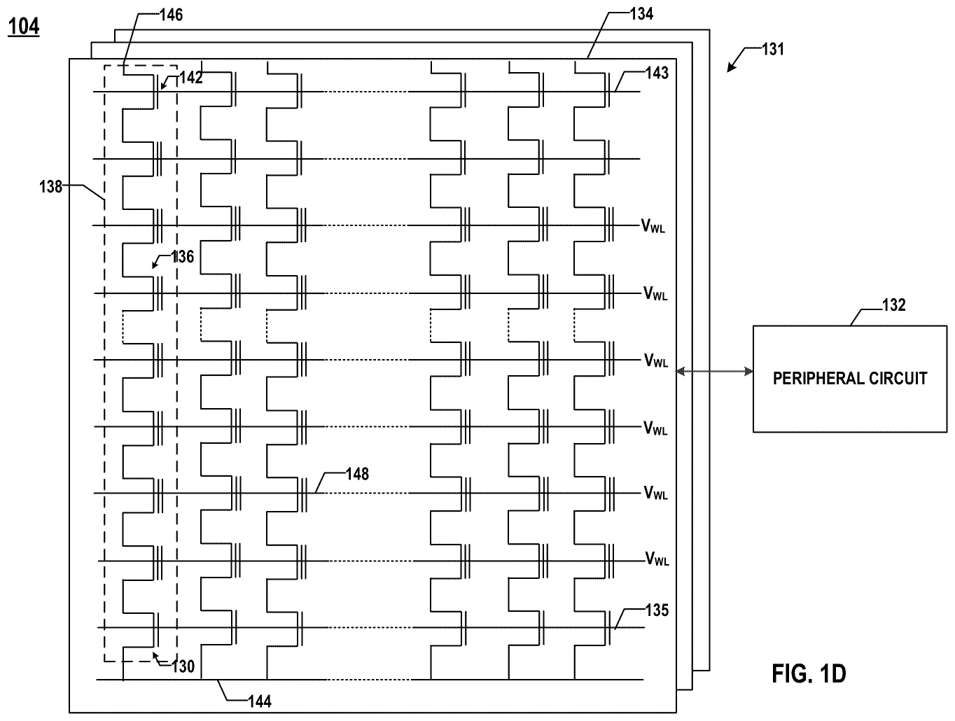

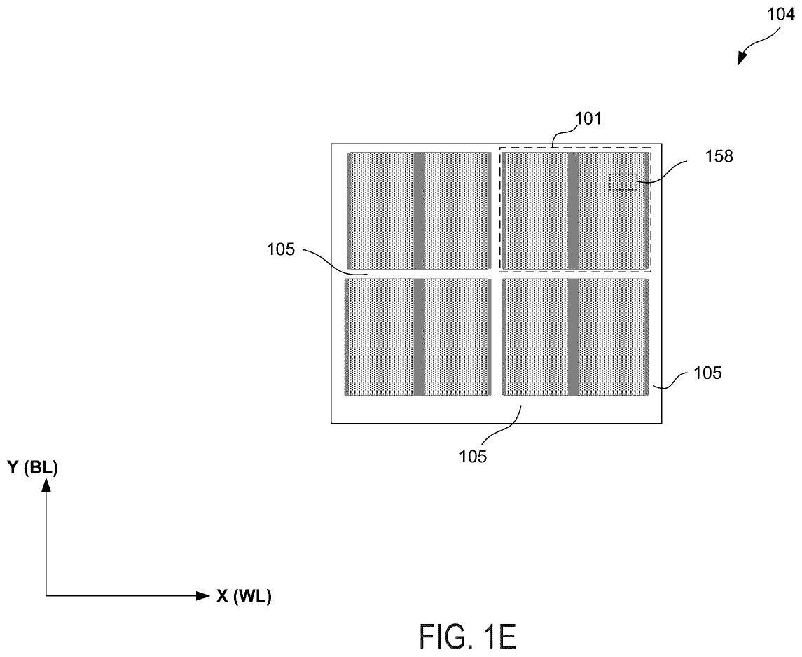

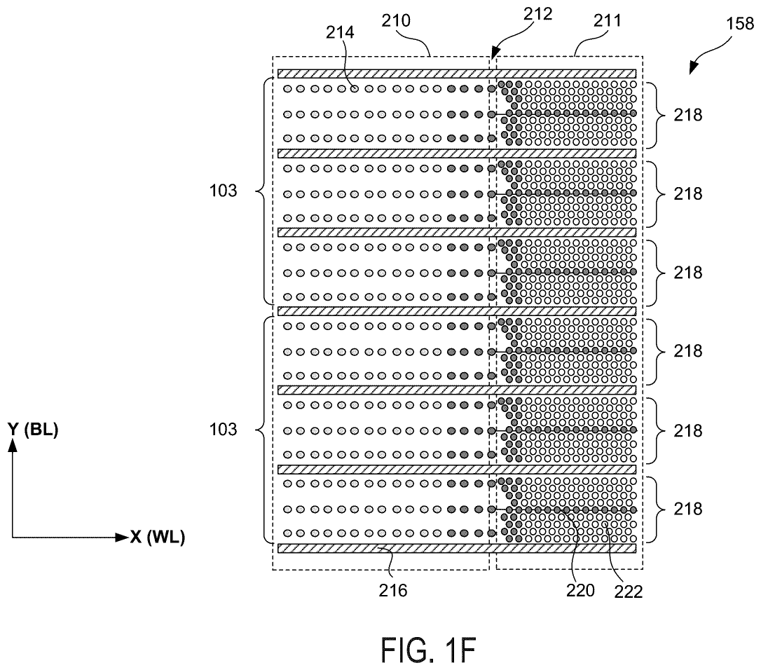

FIG. 1A illustrates a block diagram of an exemplary system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1A, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive the data to or from memory devices 104.

Memory device 104 can be any memory devices disclosed herein, such as a NAND Flash memory device. Consistent with the scope of the present disclosure, memory controller 106 can control a programming operation on non-volatile memory devices, such as three-dimensional NAND memory devices. The peripheral circuits, such as the word line drivers, may apply a multi-stage voltage ramping sequence to bit line terminals. For example, the multi-stage voltage ramping sequence can be a two-stage ramping sequence that includes first-stage and second-stage ramp-up procedures. In some embodiments, the first-stage ramp-up procedure can include applying a first voltage to a first bit line terminal while maintaining a second bit line terminal at a ground voltage level, therefore establishing a voltage difference between the first and second bit line terminals. A second-stage ramp-up procedure can include multiple sub-stages ramp-up procedures that increase voltage levels of the first and second bit line terminals to their respective nominal voltage levels.

Memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 106 can be configured to control operations of memory device 104, such as read, erase, and program operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, programming memory device 104. Memory controller 106 can communicate with an external device (e.g., host 108) according to a particular communication protocol. For example, memory controller 106 can communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 106 and one or more memory devices 104 can be integrated into various types of storage devices, for example, be included in the same package, such as a universal Flash storage (UFS) package or an eMMC package. That is, memory system 102 can be implemented and packaged into different types of end electronic products. In one example as shown in FIG. 1B, memory controller 106 and a single memory device 104 can be integrated into a memory card 112. Memory card 112 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 112 can further include a memory card connector 114 coupling memory card 112 with a host (e.g., host 108 in FIG. 1A). In another example as shown in FIG. 1C, memory controller 106 and multiple memory devices 104 can be integrated into an SSD 116. SSD 116 can further include an SSD connector 118 coupling SSD 116 with a host (e.g., host 108 in FIG. 1A). In some implementations, the storage capacity and/or the operation speed of SSD 116 is greater than those of memory card 112.

FIG. 1D illustrates a schematic circuit diagram of an exemplary memory device 104 including peripheral circuits 132, according to some aspects of the present disclosure. Memory device 104 can be an example of memory device 104 in FIG. 1A-C. Memory device 104 can include a memory cell array 131 and peripheral circuits 132 coupled to memory cell array 131. Memory cell array 131 can be a NAND Flash memory cell array in which memory cells 136 are provided in an array of NAND memory strings 138. In some implementations, each NAND memory string 138 includes a plurality of memory cells 136 coupled in series and stacked vertically. Each memory cell 136 can hold a continuous, analog value, such as an electrical voltage or charge, which depends on the number of electrons trapped within a region of memory cell 136. Each memory cell 136 can be either a floating gate type of memory cell including a floating-gate transistor or a charge trap type of memory cell including a charge-trap transistor.

In some implementations, each memory cell 136 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 136 is capable of storing more than a single bit of data in more than two memory states. For example, the MLC can store two bits per cell (also known as multi-level cell (MLC)), three bits per cell (also known as triple-level cell (TLC)), or four bits per cell (also known as a quad-level cell (QLC)).

As shown in FIG. 1D, each NAND memory string 138 can also include an SSG transistor 130 at its source end and a DSG transistor 142 at its drain end. SSG transistor 130 and DSG transistor 142 can be configured to activate select NAND memory strings 138 during read and program operations. In some implementations, the sources of NAND memory strings 138 in the same block 134 are coupled through a same source line (SL) 144. The drain of each NAND memory string 138 is coupled to a respective bit line 146, according to some implementations. In some implementations, each NAND memory string 138 is configured to be selected or unselected by applying a DSG select voltage or a DSG unselect voltage to the gate of respective DSG transistor 142 through one or more DSG lines 143 and/or by applying an SSG select voltage or an SSG unselect voltage to the gate of respective SSG transistor 130 through one or more SSG lines 135. NAND memory string 138 can thus become a select NAND memory string or an unselect NAND memory string.

As shown in FIG. 1D, NAND memory strings 138 can be organized into multiple blocks 134. In some implementations, each block 134 is the basic data unit for erase operations, i.e., all memory cells 136 on the same block 134 are erased at the same time. It should be understood that, in some implementations, the erase operation can be performed at the half-block level, at the quarter-block level, or at the level of any suitable number of blocks or any suitable number of fractions in a block. Memory cells 136 of adjacent NAND memory strings 138 can be coupled through word lines 148 that select which row of memory cells 136 is affected by read and program operations.

As shown in FIG. 1D, memory cell array 131 can include an array of memory cells 136 in a plurality of rows and a plurality of columns in each block 134. One row of memory cells 306 corresponds to one or more pages, and one column of memory cells corresponds to one NAND memory string 138, according to some implementations. The plurality of rows of memory cells 136 can be respectively coupled to word lines 148, and the plurality of columns of memory cells 136 can be respectively coupled to bit lines 146.

FIGS. 1E and 1F are cross-sectional illustrations of 3D memory device 104, according to some embodiments of the present disclosure. FIG. 1E illustrates a cross-sectional view of an exemplary 3D memory device 104 along x and y directions. FIG. 1F is a cross-sectional enlarged view of a region of 3D memory device 104 along x and y directions, according to some embodiments of the present disclosure. 3D memory device 104 can be a memory chip or any portion of a memory chip, and can include one or more memory planes 101, each of which can include memory blocks. The arrangement of memory planes, memory blocks, and memory fingers illustrated in FIGS. 1E and 1F are only provided as an example, which does not limit the scope of the present disclosure.

As shown in FIG. 1E, exemplary 3D memory device 104 includes four memory planes 101 and each memory plane 101 includes multiple memory blocks. Identical and concurrent operations can take place at each memory plane 101. Memory blocks can be megabytes (MB) in size and can be the smallest size to carry out erase operations. Each memory block can include memory cells, where each memory cell can be addressed through interconnections such as bit lines and word lines. The bit lines and word lines can be laid out perpendicularly (e.g., in rows and columns, respectively), forming an array of metal lines. The direction of bit lines and word lines are labeled as “BL” and “WL” in FIGS. 1E and 1F. The memory array is the core area in a memory device, performing storage functions.

3D memory device 104 can include a periphery region 105, an area surrounding memory planes 101. Periphery region 105 can contain many digital, analog, and/or mixed-signal circuits (not illustrated in FIG. 1E for simplicity) to support functions of the memory array, for example, page buffers, row and column decoders and sense amplifiers. Peripheral circuits can include active and/or passive semiconductor devices, such as transistors, diodes, capacitors, resistors, and any suitable devices.

Referring to FIG. 1F, a region 158 in FIG. 1E is illustrated, according to some embodiments of the present disclosure. Region 158 of 3D memory device 104 can include a staircase region 210, a core region 211 and a transition region 212. In this disclosure, memory block 103 can be included in a “memory array” or “array.” Core region 211 can include an array of memory strings 222, each including stacked memory cells. Staircase region 210 can include a staircase structure and an array of contact structures 214 formed on the staircase structure. Transition region 212 can be located in between and adjacent to core region 211 and staircase region 210. In some embodiments, slit structures 216, extending in WL direction across core region 211 and staircase region 210, can divide a memory block into multiple memory fingers 218. At least some slit structures 216 can function as the common source contact for an array of memory strings 222 in core regions 211. A top select gate cut 220 can be disposed in the middle of each memory finger 218 to divide a top select gate (TSG) of memory finger 218 into two portions, and thereby can divide a memory finger into two programmable (read/write) pages. While erase operation of a 3D NAND memory can be carried out at memory block level, read and write operations can be carried out at memory page level. In some embodiments, region 158 can include dummy memory strings for process variation control during fabrication and/or for additional mechanical support.

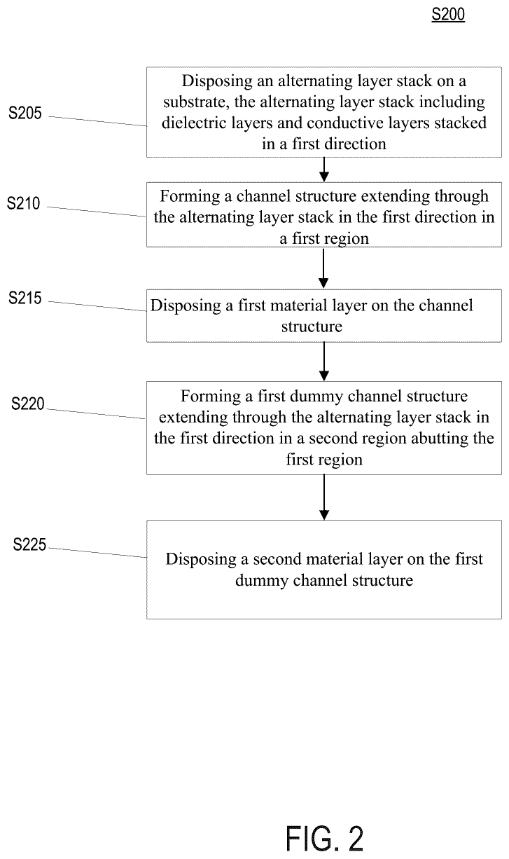

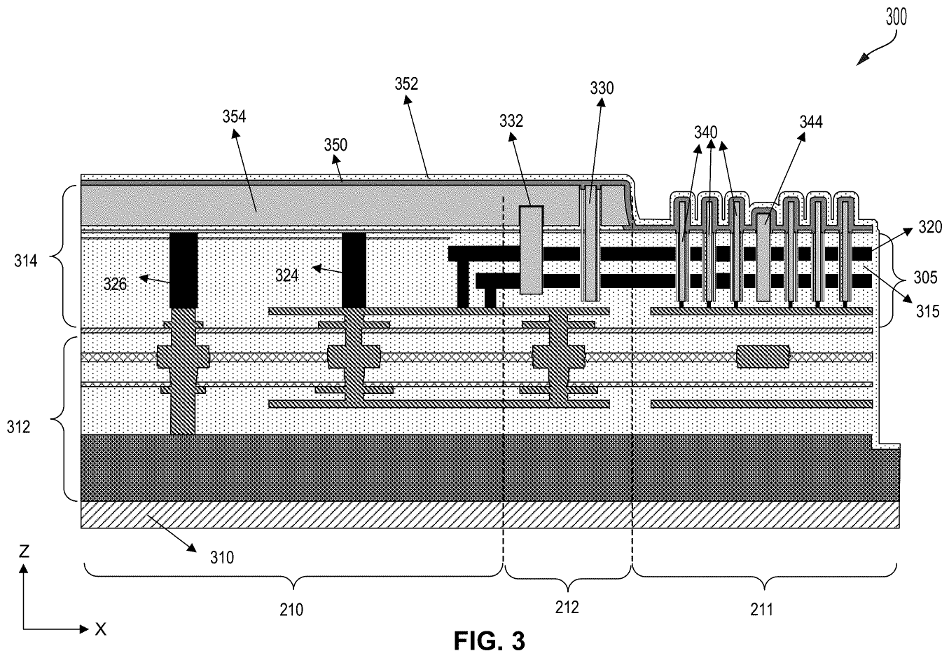

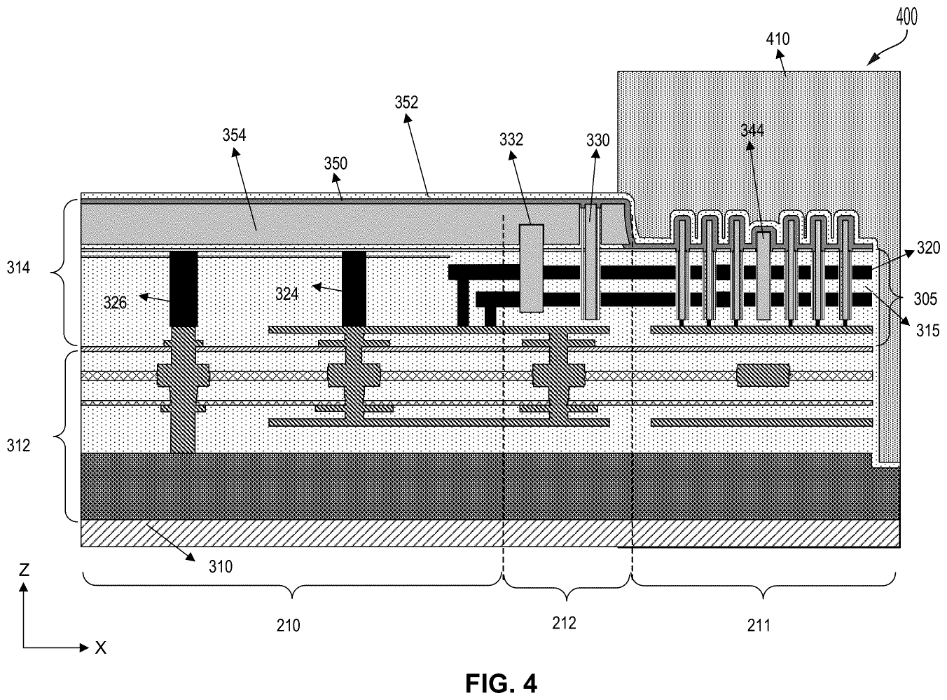

FIG. 2 illustrates a flow diagram of an exemplary method S200 for forming an exemplary three-dimensional (3D) memory device, in accordance with some embodiments of the present disclosure. Operations of method S200 can be performed in a different order and/or vary, and method S200 can include more operations that are not described for simplicity. FIGS. 3-8 are cross-sectional views of semiconductor structure 300 during various fabrication stages for forming the exemplary three-dimensional (3D) memory device. In some embodiments, semiconductor structure 300 can be a portion of a 3D NAND memory device. The fabrication processes provided here are exemplary. Alternative processes in accordance with this disclosure can be performed and are not shown in these figures.

Referring to FIG. 2, at operation S205, an alternating layer stack is disposed on a substrate. According to some aspects, the alternating layer stack can include dielectric layers and conductive layers stacked in a first direction.

FIGS. 3-8 illustrate schematic cross-sectional views of various fabrication stages of a 3D memory device, according to some embodiments of the present disclosure.

As shown in FIG. 3, semiconductor structure 300 can include memory cell region 314, peripheral circuit region 312 and substrate 310 stacked in a vertical direction (e.g., z direction). Memory cell region 314 can be disposed on peripheral circuit region 312 and substrate 310. According to some aspects, memory cell array region 314 can include memory cell array 131 in FIG. 1D. Peripheral circuit region 312 can include peripheral circuits 132 in FIG. 1D coupled to memory cell array 131.

As shown in FIG. 3, semiconductor structure 300 can include staircase region 210, core region 211 and transition region 212 arranged in a horizontal direction (e.g., x direction). Transition region 212 can be arranged in between staircase region 210 and core region 211 in the horizontal direction (e.g., x direction). Core region 211 can include one or more channel structures, such as channel structures 340. Transition region 212 can include one or more dummy channel structures, such as dummy channel structure 330 and dummy channel structure 332. In some aspects, the dummy channel structures and channel structures may be formed by the same process. The dummy channel structures and channel structures may include the same layer structure.

Semiconductor structure 300 can include an alternating layer stack 305 stacked in the vertical direction (e.g., z direction), according to some embodiments. In some embodiments, a dielectric layer 315 and a conductive layer 320 can be alternatingly disposed on peripheral circuits 132 and substrate 310 to form alternating layer stack 305. In some embodiments, dielectric layer 315 can be formed using a silicon nitride material. In some embodiments, conductive layer 320 can be formed using a silicon oxide material. Dielectric layer 315 and conductive layer 320 can be disposed using one or more thin-layer deposition processes including, but not limited to, chemical vapor deposition (CVD), plasma-enhanced CVD (PECVD), physical vapor deposition (PVD), atomic layer deposition (ALD), plasma-enhanced ALD (PEALD), or any combinations thereof. In some embodiments, thicknesses of dielectric layers 315 can be the same or different. Similarly, thicknesses of conductive layers 320 can be the same or different. According to some aspects, as shown in FIG. 3, alternating layer stack 305 may be included in memory cell region 314, staircase region 210, core region 211 and transition region 212.

In some aspects, staircase region 210 can include alternating layer stack 305. One of the dielectric layers in alternating layer stack 305 can be disposed over a first portion of one of the conductive layers in alternating layer stack 305. A landing pad may be disposed over a second portion of the one of the conductive layers in alternating layer stack 305. The dielectric layers or the conductive layers in alternating layer stack 305 can form a staircase structure in the horizontal direction (e.g., x direction).

Substrate 310 can include silicon (e.g., single crystalline silicon), silicon germanium (SiGe), germanium (Ge), silicon on insulator (SOI), germanium on insulator (GOI), gallium arsenide (GaAs), gallium nitride, silicon carbide, glass, III-V compound, any other suitable materials or any combinations thereof. In some embodiments, substrate can be double-side polished prior to device fabrication. Substrate can be a multi-layer structure including one or more suitable sub-layers. For example, substrate can include a base formed using silicon and an oxide layer formed of silicon oxide.

Referring to FIG. 2, at operation S210, a channel structure is formed extending through the alternating layer stack in the first direction in a first region.

As shown in FIG. 3, channel structures 340 can be formed in core region 211 by etching alternating layer stack 305. Each of channel structures 340 can include a memory layer and a channel layer. The memory layer and/or the channel layer may include a multi-layer structure including one or more suitable sub-layers. According to some aspects, a gate isolation structure 344 can be formed in core region 211 by etching alternating layer stack 305.

As shown in FIG. 3, dummy channel structure 330 can be formed extending through alternating layer stack 305 in the first direction in transition region 212. Dummy channel structure 330 can be formed by etching alternating layer stack 305. According to some aspects, dummy channel structure 332 can be formed extending through alternating layer stack 305 in the first direction in transition region 212. Dummy channel structure 332 can be used to support the replacement gate layer process. Dummy channel structure 332 can include the same materials as dummy channel structure 330, or different materials. For example, dummy channel structure 332 can be filled with insulating materials, and dummy channel structure 330 can include a conductive layer, such as the conductive layer same as the channel structures 340. According to some aspects, as shown in FIG. 3, a depth of dummy channel structure 330 can be formed greater than a depth of dummy channel structure 332 in the first direction (e.g., z direction). According to some aspects, as shown in FIG. 3, a depth of dummy channel structure 330 can be formed greater than a depth of channel structures 340 in the first direction (e.g., z direction).

As shown in FIG. 3, semiconductor structure 300 can include a contact structure 324 in staircase region 210. Contact structure 324 can be electrically connected with conductive layer 320. Contact structure 324 can include conductive materials, such as polysilicon or metal materials. According to some aspects, semiconductor structure 300 can include a barrier structure 326. Barrier structure 326 can be located at the edge of staircase region 210 away from core region 211. Barrier structure 326 can include conductive materials, such as polysilicon or metal materials. Barrier structure 326 can be used to prevent water vapor from entering the interior of semiconductor structure 300, such as staircase region 210, core region 211 and transition region 212, to avoid affecting the performance of the memory device.

Referring to FIG. 2, at operation S215, a first material layer is disposed on the channel structure.

As shown in FIG. 3, first material layer 350 can be formed above channel structures 340 and dummy channel structure 330. First material layer 350 can include a conductive layer, such as a source layer including a polysilicon material. First material layer 350 can be electrically connected with the channel layer (e.g., polysilicon) in channel structures 340. According to some aspects, first material layer 350 can be formed on memory cell region 314 and then bonding with peripheral circuit region 312. The sequence of processes, and the drawings associated with forming first material layer 350 can be illustrated as examples and not limited to the present disclosure.

According to some aspects, as shown in FIG. 3, semiconductor layer 354 can be formed on dummy channel structure 332 in transition region 212. Semiconductor layer 354 can be formed on alternating layer stack 305 in staircase region 210 and transition region 212. Semiconductor layer 354 can be formed prior to forming first material layer 350.

According to some aspects, as shown in FIG. 3, a dielectric layer 352, including for example, an oxide or a nitride material, may be formed on first material layer 350. The thickness and size of first material layer 350 or dielectric layer 352 are illustrated as examples only. For example, the thickness of first material layer 350 can be greater than or equal to the thickness of semiconductor layer 354 (e.g., polysilicon layer). According to some aspects, first material layer 350 and dielectric layer 352 can be formed after the bonding process of peripheral circuit region 312 and memory cell region 314.

According to some aspects, first material layer 350, dielectric layer 352 and/or semiconductor layer 354 can be formed using one or more thin-layer deposition processes including, but not limited to, chemical vapor deposition (CVD), plasma-enhanced CVD (PECVD), physical vapor deposition (PVD), atomic layer deposition (ALD), plasma-enhanced ALD (PEALD), or any combinations thereof.

Referring to FIG. 2, at operation S220, a first dummy channel structure is formed extending through the alternating layer stack in the first direction in a second region abutting the first region.

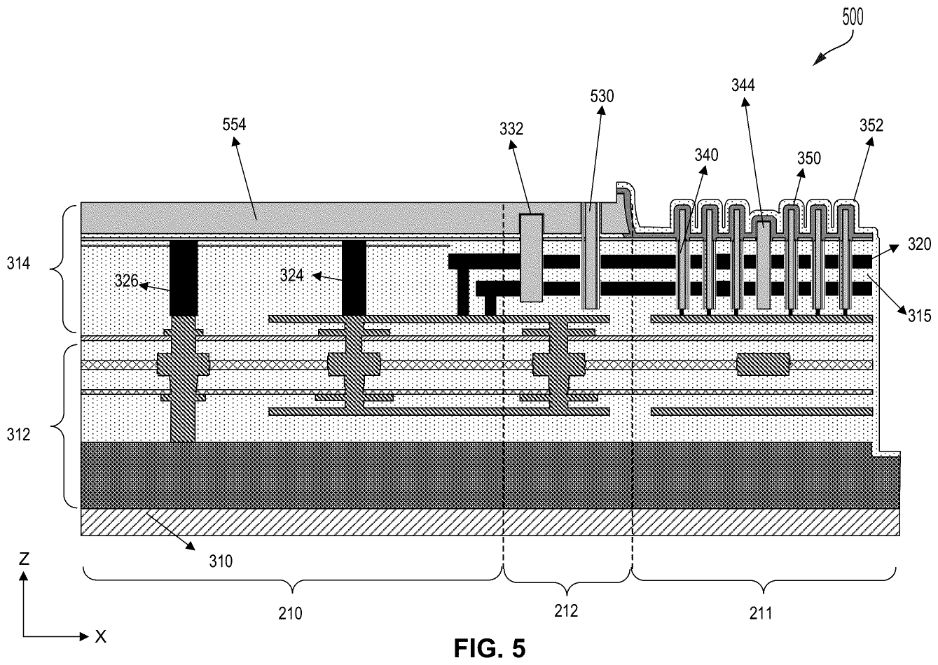

As shown in FIGS. 4-5, first dummy channel structure 530 is formed extending through alternating layer stack 305 in the first direction (e.g., z direction) in transition region 212. As shown in FIG. 4, semiconductor structure 400 can be formed by forming a protective layer 410 on semiconductor structure 300. Protective layer 410 (e.g., photoresist, hard mask) can be formed to protect first material layer 350 in the core region 211. Protective layer 410 can cover core region 211 and expose at least a portion of transition region 212.

According to some aspects, the location or area of core region 211 or transition region 212 covered by protective layer 410 may not be limited. The location or are of core region 211 or transition region 212 covered by protective layer 410 can be adjusted, such as according to different fabrication process requirements. For example, an entire region of transition region 212 can be completely exposed relative to protective layer 410, and the edge of core region 211 close to transition region 212 can be exposed relative to protective layer 420.

As shown in FIG. 5, semiconductor structure 500 can be formed by removing protective layer 410. Protective layer 410 can be removed by etching (e.g., wet etch). A portion of dielectric layer 352 and a portion of first material layer 350 exposed relative to protective layer 410 can be removed by etching (e.g., wet etch) in staircase region 210 and/or transition region 212. For example, a portion of first material layer 350 disposed above dummy channel structure 330 and dummy channel structure 332 can be removed. According to some aspects, when removing the portion of first material layer 350, a portion of dielectric layer 352 not covered by protective layer 410 can be removed to expose dummy channel structure 330. After removing protective layer 410, in the first direction (e.g., z direction), the height of first material layer 350 in core region 211 can be different from the height of first material layer 350 in transition region 212. For example, a first portion of first material layer 350 in transition region 212 covering the dummy channel structure 330 and dummy channel structure 332 can be completely removed. The portion of dielectric layer 352 covering the first portion of first material layer 350 in staircase region 210 and transition region 212 can be completely removed.

According to some aspects, when the first portion of first material layer 350 is removed, the conductive layer in dummy channel structure 330 can be removed when exposed relative to protective layer 410. First dummy channel structure 530 can be formed by etching a top portion of dummy channel structure 330. For example, first dummy channel structure 530 can include a remaining portion of dummy channel structure 330 after the first portion of first material layer 350 is removed. The height of first dummy channel structure 530 can be smaller than the height of dummy channel structure 330 in the first direction.

Referring to FIG. 2, at operation S225, a second material layer is disposed on the first dummy channel structure.

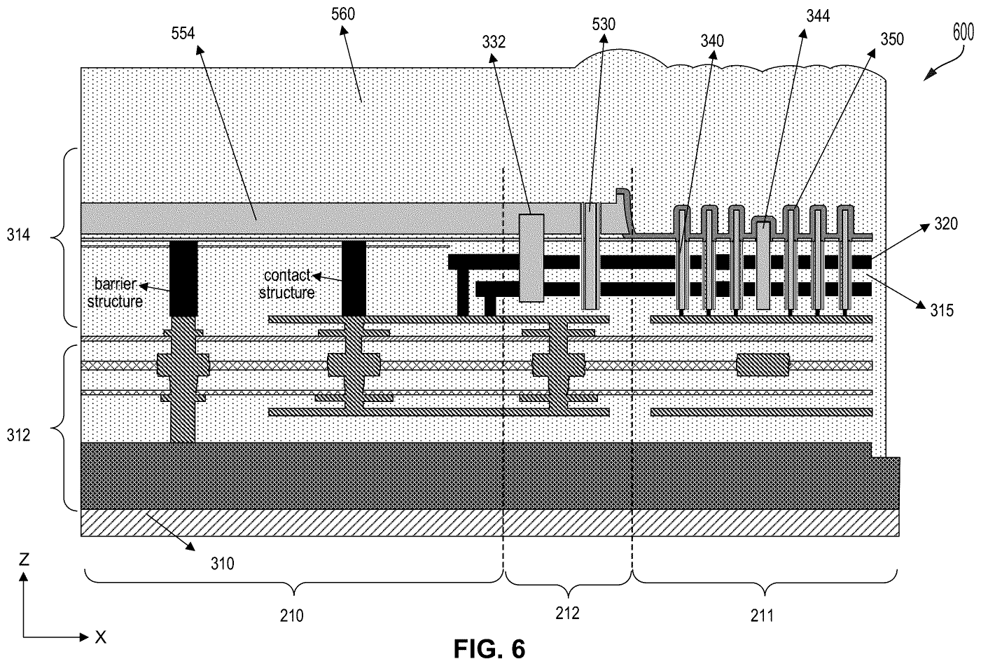

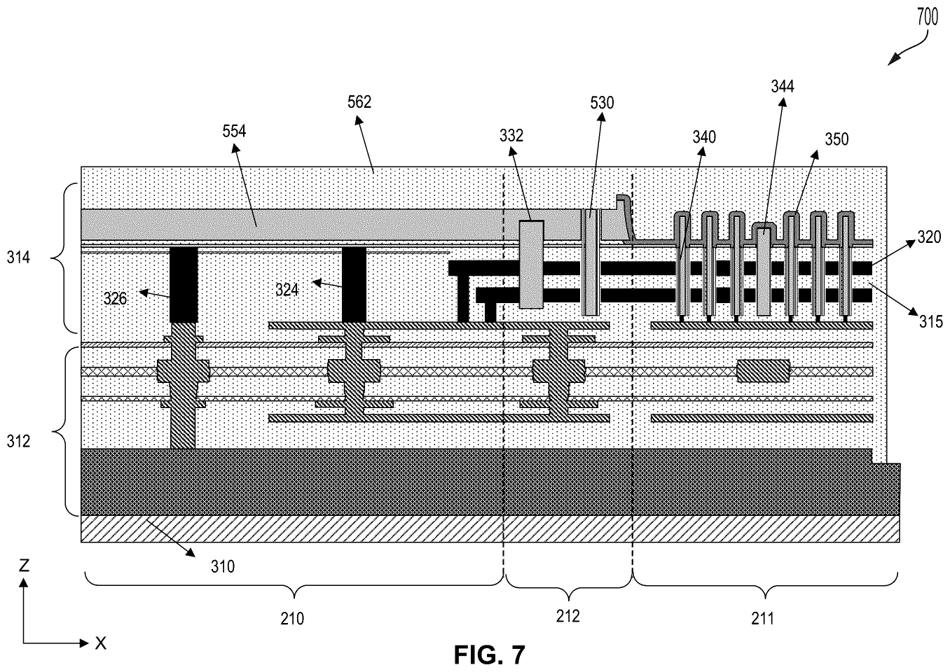

As shown in FIGS. 6-7, second material layer 560 can be disposed on first dummy channel structure 530. In semiconductor structure 600, second material layer 560 can be disposed on semiconductor structure 500 including the remaining portions of first material layer 350 and/or dielectric layer 352.

Second material layer 560 can include a dielectric layer, such as including an oxide or nitride material. Second material layer 560 can cover staircase region 210, core region 211 and transition region 212 in horizontal direction (e.g., x direction). According to some aspects, second material layer 560 can include the same material as dielectric layer 352, such as an oxide material.

According to some aspects, second material layer 560 can be formed using one or more thin-layer deposition processes including, but not limited to, chemical vapor deposition (CVD), plasma-enhanced CVD (PECVD), physical vapor deposition (PVD), atomic layer deposition (ALD), plasma-enhanced ALD (PEALD), or any combinations thereof.

As shown in FIG. 7, in semiconductor structure 700, second material layer 560 can be polished to form second material layer 562, such that the top surface of second material layer 562 can be flat. The thickness and method of polishing second material layer 560 may not be limited. For example, chemical mechanical polishing (CMP) may be used to polish the second material layer 560.

As shown in FIG. 7, in the first direction (e.g., z direction), the height of first material layer 350 in core region 211 can be different from the height of first material layer 350 in transition region 212. First material layer 350 can cover core region 211, and at least part of transition region 212 that does not include first material layer 350.

According to some aspects, the orthographic projection of first dummy channel structure 530 may not overlap or connect with the orthographic projection of first material layer 350. A top portion of first dummy channel structure 530 may not be connected with or in contact with first material layer 350.

According to some aspects, semiconductor layer 354 can include a discontinuity, such as for example, a bulge region. The height of a first side of semiconductor layer 354 close to core region 211 can be greater than the height of a second side away from core region 211.

According to some aspects, first material layer 350 and second material layer 562 can include different materials. Second material layer 562 can be spaced apart from the first dummy channel structure 530 in a second direction (e.g. x direction). According to some aspects, the first direction is perpendicular to the second direction.

Various embodiments in accordance with the present disclosure provide structures and fabricating methods for a memory device.

As described above, in the process of forming a memory device, the depth of a dummy channel structure and a channel structure formed may be inconsistent, such as the depth or height of the dummy channel structure may be greater than the depth or height of the channel structure. In the subsequent processes, an electrical connection between the conductive layer in the dummy channel structure and the source layer (e.g., polysilicon) connected with the channel structure may cause leakage problems, which may affect the performance of the memory device.

The leakage problem of the dummy channel structure may be solved by the memory device and methods disclosed in the present disclosure, for example, by reverse etching. In some aspects, a portion of the source layer, which is electrically connected with the conductive layer in the dummy channel structure, may be removed. For example, a mask may be used to expose the source layer above the dummy channel structure to remove the source layer above the dummy channel structure. The conductive layer in the dummy channel structure and source layer may be separated so that the bottom of the dummy channel structure may be insulated from the source layer.

According to some aspects, a portion of the conductive layer in the dummy channel structure may be removed. The conductive layer in the dummy channel structure and the source layer connected with the channel structure may be separated, so that a portion (e.g., bottom side) of the dummy channel structure may be insulated from the source layer connected with the channel structure. The leakage problem caused by the electrical connection between the conductive layer in the dummy channel structure and the source layer (e.g., polysilicon) connected with the channel structure may be resolved. According to some aspects, the insulation between the portion (e.g., bottom side) of the dummy channel structure and the source layer connected with the channel structure may increase or improve the process window for forming the dummy channel structure or the memory device.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
an alternating layer stack comprising dielectric layers and conductive layers stacked in a first direction;
a channel structure extending through the alternating layer stack in a first direction in a first region, wherein a first material layer is disposed on the channel structure; and
a first dummy channel structure extending through the alternating layer stack in the first direction in a second region abutting the first region, wherein a second material layer is disposed on the first dummy channel structure, wherein the first material layer and the second material layer are different materials, wherein the first material layer is spaced apart from the first dummy channel structure in a second direction, and wherein the first direction is perpendicular to the second direction.

2. The memory device of claim 1, wherein the second material layer is disposed on the first material layer.

3. The memory device of claim 1, wherein the second material layer comprises a dielectric material.

4. The memory device of claim 1, wherein the first material layer comprises a conductive material.

5. The memory device of claim 1, further comprising a second dummy channel structure in the second region, wherein a third material layer is disposed on the second dummy channel structure.

6. The memory device of claim 5, wherein the third material layer comprises a conductive material.

7. The memory device of claim 5, wherein the second dummy channel structure is filled with an insulating material.

8. The memory device of claim 5, wherein a depth of the first dummy channel structure is greater than a depth of the second dummy channel structure in the first direction.

9. The memory device of claim 1, wherein the first dummy channel structure is not electrically connected with the first material layer.

10. The memory device of claim 1, wherein a depth of the first dummy channel structure is greater than a depth of the channel structure in the first direction.

11. The memory device of claim 1, wherein the first material layer is disposed on a channel layer of the channel structure, and wherein the first material layer is electrically connected with the channel layer.

12. The memory device of claim 1, further comprising a staircase structure in a third region abutting the second region, wherein the staircase structure comprises the alternating layer stack.

13. The memory device of claim 12, further comprising a contact structure in the third region, wherein the contact structure is electrically connected with one of the conductive layers of the alternating layer stack.

14. The memory device of claim 12, further comprising a barrier structure in the third region, wherein the barrier structure comprises a conductive material.

15. The memory device of claim 12, wherein one of the dielectric layers is disposed over a first portion of one of the conductive layers, and wherein a landing pad disposed over a second portion of the one of the conductive layers.

16. A memory system, comprising:
a controller; and
a memory device coupled to the controller, the memory device comprising:
an alternating layer stack comprising dielectric layers and conductive layers stacked in a first direction;
a channel structure extending through the alternating layer stack in a first direction in a first region, wherein a first material layer is disposed on the channel structure; and
a first dummy channel structure extending through the alternating layer stack in the first direction in a second region abutting the first region, wherein a second material layer is disposed on the first dummy channel structure, wherein the first material layer and the second material layer are different materials, and wherein the first material layer is spaced apart from the first dummy channel structure in a second direction and wherein the first direction is perpendicular to the second direction.

17. A method for forming a memory device, comprising:
disposing an alternating layer stack on a substrate, wherein the alternating layer stack comprises dielectric layers and conductive layers stacked in a first direction;
forming a channel structure extending through the alternating layer stack in the first direction in a first region;
disposing a first material layer on the channel structure;
forming a first dummy channel structure extending through the alternating layer stack in the first direction in a second region abutting the first region; and
disposing a second material layer on the first dummy channel structure, wherein the first material layer and the second material layer are different materials, wherein the first material layer is spaced apart from the first dummy channel structure in a second direction and wherein the first direction is perpendicular to the second direction.

18. The method of claim 17, further comprising: disposing the second material layer on the first material layer.

19. The method of claim 17, wherein the forming the first dummy channel structure comprising:
disposing the first material layer on the first dummy channel structure; and
removing the first material layer.

20. The method of claim 17, wherein the disposing the first material layer on the channel structure further comprising:
disposing a protective layer on the first material layer, and
removing the protective layer.
